(19) United States
(12) Patent Application Publication
(10) Pub. No.: US 2014/0302687 A1
(43) Pub. Date: Oct. 9, 2014

(54) Substrate Processing Device, Method for Manufacturing Semiconductor Device, and Vaporizer

(71) Applicant: Hitachi Kokusai Electric Inc., Tokyo (JP)

(72) Inventors: Hiroshi ASHIHARA, Toyama (JP); Harunobu SAKUMA, Toyama (JP); Hideto TATENO, Toyama (JP); Yuichi WADA, Toyama (JP)

(21) Appl. No.: 14/310,442

(22) Filed: Jun. 20, 2014

Related U.S. Application Data
(63) Continuation of application No. PCT/JP2012/083047, filed on Dec. 20, 2012.

(30) Foreign Application Priority Data
Dec. 20, 2011 (JP) 2011-278887

(51) Int. Cl. H01L 21/02; F22B 1/28

(52) U.S. Cl. CPC H01L 21/02271; F22B 1/284; H01L 21/0217
USPC 438/780; 118/726; 392/394

(57) ABSTRACT

A substrate processing apparatus includes: a reaction chamber configured to process a substrate; a vaporizer including a vaporization container into which a processing liquid including hydrogen peroxide or hydrogen peroxide and water is supplied, a processing liquid supply unit configured to supply the processing liquid to the vaporization container, and a heating unit configured to heat the vaporization container; a gas supply unit configured to supply a processing gas generated by the vaporizer into the reaction chamber; an exhaust unit configured to exhaust an atmosphere in the reaction chamber; and a control unit configured to control the heating unit and the processing liquid supply unit such that the processing liquid supply unit supplies the processing liquid to the vaporization container while the heating unit heats the vaporization container.

### CROSS REFERENCE TO RELATED APPLICATIONS

This application is a continuation of International Application No. PCT/JP2012/083047, filed on Dec. 20, 2012, entitled “Substrate Processing Device, Method for Manufacturing Semiconductor Device, and Vaporizer,” which claims priority under 35 U.S.C. §119 to Application No. JP 2011-278887 filed on Dec. 20, 2011, entitled “Substrate Processing Device, Method for Manufacturing Semiconductor Device, and Vaporizer,” the entire contents of which are hereby incorporated by reference.

### FIELD OF THE INVENTION

The present invention relates to a substrate processing apparatus for processing a substrate using a gas, a method of manufacturing a semiconductor device, and a vaporizer.

### BACKGROUND

According to miniaturization of a large scale integrated circuit (hereinafter, referred to as LSI), a processing technology of controlling leakage current interference between transistor devices is subject to technical problems. In order to separate the devices of the LSI, a method of forming a gap such as a groove, a hole, or the like, between the devices to be separated, on silicon (Si), which becomes a substrate, and accumulating an insulating material in the gap is employed. A silicon oxide film (SiO₂) is often used as an insulating material, and formed by oxidation of a Si substrate itself, chemical vapor deposition (hereinafter, referred to as CVD), or spin on dielectric (hereinafter, referred to as SOD).

Due to the miniaturization in recent times, a burying method by the CVD method with respect to burial of a fine structure, in particular, burial of an oxide in a gap structure deep in a vertical direction or narrow in a horizontal direction has been subjected to a technical limit. Due to the above-described background, use of a burying method using an oxide having fluidity, i.e., employment of SOD, is being increased. In the SOD, an application insulating material including an inorganic or organic ingredient, which is called as spin on glass (SOG), is used. While the material was employed in a manufacturing process of the LSI before a CVD oxide film appeared, since the processing technology has an imprecise processing dimension of 0.35 μm to 1 μm, a modification method after application is allowed by performing heat treatment of about 400° C. in a nitrogen atmosphere. In the LSI in recent years, since a minimum processing dimension represented by a dynamic random access memory (DRAM) or a flash memory is smaller than a width of 50 nm, the number of device makers using polysilazane instead of the SOG has been increasing.

The polysilazane is a material obtained by a catalytic reaction of, for example, dichlorosilane or trichlorosilane and ammonia, and is used when a thin film is formed by applying the material on the substrate using a spin coater. A film thickness is adjusted according to a molecular weight or viscosity of the polysilazane, or a number of revolutions of the coater.

The polysilazane includes nitrogen as an impurity caused by ammonia at the time of a manufacturing process. In order to remove the impurities from the deposited film formed using the polysilazane and obtain a dense oxide film, additional moisture and heat treatment are needed after the application. A method of reacting hydrogen with oxygen in a heat treatment furnace body to generate moisture is known as the method of adding the moisture, and the dense oxide film is obtained by adding the generated moisture to the polysilazane film and applying heat to the film. In the case of a shallow trench isolation (STI) for separating the devices, a maximum temperature of the heat treatment may become about 1,000° C.

Reduction in thermal load of the transistor is required while the polysilazane is widely used in the LSI process. The reasons for reducing the thermal load are prevention of excessive diffusion of an impurity such as boron, arsenic, phosphorous, or the like implanted for an operation of the transistor, prevention of condensation of metal silicide for an electrode, prevention of variation in performance of a work function metal material for a gate, writing on a memory device, acquisition of reading repetition lifetime, and so on. Accordingly, in a process of providing moisture, effectively providing the moisture is directly related to reduction in thermal load of a heat treatment process, which is performed thereafter.

See also Japanese Unexamined Patent Application, First Publication No. 2010-87475.

### SUMMARY

An object of the present invention is to provide a substrate processing apparatus, a method of manufacturing a semiconductor device, and a vaporizer that are capable of improving manufacturing quality of the semiconductor device and improving manufacturing throughput.

According to an aspect of the present invention, there is provided a substrate processing apparatus including: a reaction chamber configured to process a substrate; a vaporizer including a vaporization container into which a processing liquid including hydrogen peroxide or hydrogen peroxide and water is supplied, a processing liquid supply unit configured to supply the processing liquid to the vaporization container, and a heating unit configured to heat the vaporization container; a gas supply unit configured to supply a processing gas generated by the vaporizer into the reaction chamber; an exhaust unit configured to exhaust an atmosphere in the reaction chamber; and a control unit configured to control the heating unit and the processing liquid supply unit such that the processing liquid supply unit supplies the processing liquid to the vaporization container while the heating unit heats the vaporization container.

According to another aspect of the present invention, there is provided a method of manufacturing a semiconductor device including: loading a substrate into a reaction chamber; heating a vaporization container installed at a vaporizer; supplying a processing liquid including hydrogen peroxide or hydrogen peroxide and water into the vaporization container; and supplying a processing gas generated by the vaporizer into the reaction chamber.

According to still another aspect of the present invention, there is provided a vaporizer including: a processing liquid supply unit configured to supply a processing liquid including hydrogen peroxide or a mixed liquid of hydrogen peroxide and water into a vaporization container; a heating unit configured to heat the vaporization container; and an exhaust port configured to discharge a processing gas generated from the processing liquid.

### BRIEF DESCRIPTION OF THE DRAWINGS

FIG. 1 is a view showing a configuration of a substrate processing apparatus according to an embodiment of the present invention;

FIG. 2 is a view exemplarily showing a structure of a vaporizer according to a first embodiment of the present invention;

FIG. 3 is a view exemplarily showing a structure of a controller according to the embodiment of the present invention;

FIG. 4 is a view exemplarily showing a flow chart of a substrate processing process according to the embodiment of the present invention;

FIG. 5 is a view exemplarily showing a structure of a vaporizer according to a second embodiment of the present invention;

FIG. 6 is a view exemplarily showing the structure of the vaporizer according to the second embodiment of the present invention;

FIG. 7 is a view exemplarily showing the structure of the vaporizer according to the second embodiment of the present invention;

FIG. 8 is a view exemplarily showing a structure of a vaporizer according to a third embodiment of the present invention;

FIG. 9 is a view exemplarily showing the structure of the vaporizer according to the third embodiment of the present invention;

FIG. 10 is a view exemplarily showing the structure of the vaporizer according to the third embodiment of the present invention;

FIG. 11 is a view exemplarily showing the structure of the vaporizer according to the third embodiment of the present invention;

FIG. 12 is a view exemplarily showing the structure of the vaporizer according to the third embodiment of the present invention;

FIG. 13 is a view exemplarily showing the structure of the vaporizer according to the third embodiment of the present invention;

FIG. 14 is a view exemplarily showing the structure of the vaporizer according to the third embodiment of the present invention;

FIG. 15 is a view exemplarily showing the structure of the vaporizer according to the third embodiment of the present invention;

FIG. 16 is a view exemplarily showing the structure of the vaporizer according to the third embodiment of the present invention;

FIG. 17 is a view exemplarily showing the structure of the vaporizer according to the third embodiment of the present invention; and

FIG. 18 is a view exemplarily showing the structure of the vaporizer according to the third embodiment of the present invention.

### DETAILED DESCRIPTION

### Embodiments of the Present Invention

Hereinafter, an embodiment of the present invention will be described.

(1) Configuration of Substrate Processing Apparatus

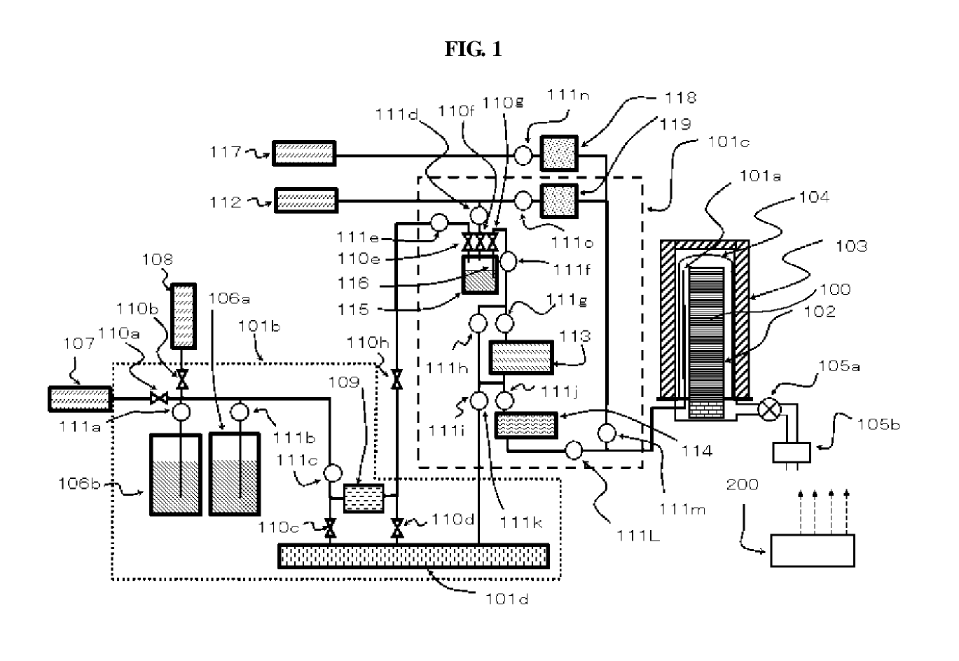

First, a configuration example of a substrate processing apparatus configured to perform a method of manufacturing a semiconductor device according to the embodiment will be described using FIG. 1. FIG. 1 is a cross-sectional view showing a configuration of the substrate processing apparatus. The substrate processing apparatus is an apparatus for processing a substrate using liquid containing vaporized oxygen. For example, the substrate processing apparatus is an apparatus for processing a wafer 100, which is a substrate formed of silicon or the like. In addition, a substrate having a fine structure serving as a concavo-convex structure (a gap) may be used as the wafer 100. The substrate having the fine structure is referred to as a substrate having a structure with a high aspect ratio, for example, a groove (a concave section) having a small width of about 10 nm to 50 nm in a horizontal direction.

As shown in FIG. 1, the substrate processing apparatus includes a gas supply unit, a boat 102 configured to hold the wafer 100, a heater 103 serving as a reaction chamber heating unit configured to heat the wafer 100, a reaction chamber 104, an exhaust unit configured to exhaust an atmosphere in the reaction chamber, and a controller 200.

Next, the gas supply unit will be described. The gas supply unit includes a gas supply port 101a configured to supply a processing gas into the reaction chamber 104. According to necessity, the gas supply unit may include at least one of a processing liquid supply unit 101b, a vaporization unit 101c serving as a vaporization part, and a drain 101d.

The processing liquid supply unit 101b includes a processing liquid tank 106a, a processing liquid preliminary tank 106b, a purge water supply unit 107, a purge air supply unit 108, a processing liquid pump 109, manual valves 110a, 110b, 110c and 110d capable of isolating the above parts, and automatic valves 111a, 111b and 111c controlled by the controller 200.

The purge water supply unit 107, the purge air supply unit 108 and the manual valves 110a and 110b are used upon maintenance of the processing liquid supply unit 101b, i.e., when the inside of the processing liquid supply unit 101b is cleaned, and the manual valve 110a and the manual valve 110b is normally in a closed state.

Liquid containing oxygen is filled in the processing liquid tank 106a and the processing liquid preliminary tank 106b. The liquid containing oxygen includes any one among hydrogen peroxide (H₂O₂), ozone (O₃), nitrous oxide (NO), carbon dioxide (CO₂) and carbon monoxide (CO) or a mixed liquid thereof. In the following example, an example using hydrogen peroxide is described.

The vaporization unit 101c includes a purge gas supply unit 112, a liquid flow rate control apparatus 113, a vaporizer 114, a reserve tank 115, manual valves 110e, 110f and 110g capable of isolating the above parts, and automatic valves 111d, 111e, 111f, 111g, 111h, 111i, 111k, 111L, 111m, 111n and 111o configured to be opened and closed by the controller 200.

The reserve tank 115 is used to regulate a supply pressure of the processing liquid into the liquid flow rate control apparatus 113. The liquid supplied from the processing liquid pump 109 may become a discontinuous flow. Accordingly, the processing liquid supplied from the processing liquid supply unit 101b is supplied into the reserve tank 115, and the processing liquid is forced to the liquid flow rate control apparatus 113 by the gas pressure from the purge gas supply unit 112. As the gas pressure is used, a supply amount of the processing liquid may be constant. The vaporizer 114 is configured to continuously generate a certain amount of vaporized processing liquid and supply the vaporized processing liquid into the reaction chamber 104 as the processing liquid having a flow rate controlled by the liquid flow rate control apparatus 113 is supplied.

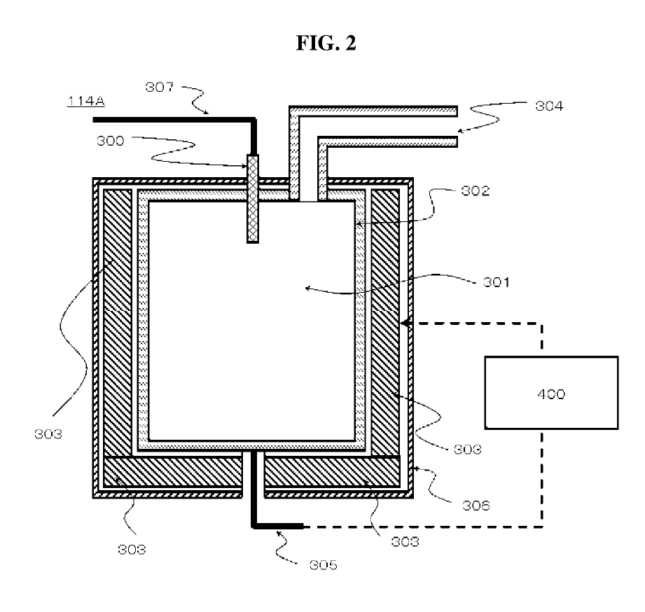

Here, a specific structure of the vaporizer 114 will be described using a vaporizer 114A of FIG. 2.

The vaporizer 114A uses a dropping method of vaporizing the processing liquid by adding the processing liquid in drops into a vaporization container 302 which is heated. The vaporizer 114A includes a processing liquid dropping nozzle 300 serving as a processing liquid supply unit, the vaporization container 302 to be heated, a vaporization space 301 implemented by the vaporization container 302, a vaporizer heater 303 serving as a heating unit configured to heat the vaporization container 302, an exhaust port 304 configured to exhaust the vaporized processing liquid into the reaction chamber, a thermocouple 305 configured to measure a temperature of the vaporization container 302, a temperature controller 400 configured to control the temperature of the vaporizer heater 303 based on the temperature measured by the thermocouple 305, and a processing liquid supply pipe 307 configured to supply the processing liquid into the processing liquid dropping nozzle 300. The vaporization container 302 is heated by the vaporizer heater 303 such that the processing liquid arrives in drops at the vaporization container and is simultaneously vaporized. In addition, heating efficiency of the vaporization container 302 by the vaporizer heater 303 is improved, and a heat insulating material 306 capable of insulating the vaporizer 114A from another unit is installed. The vaporization container 302 is formed of quartz, carbonized silicon, or the like, to prevent a reaction with the processing liquid. The temperature of the vaporization container 302 is decreased according to the temperature or the vaporization heat of the dropped processing liquid. Accordingly, in order to prevent a decrease in temperature, carbonized silicon having high thermal conductivity may be preferably used. In addition, when the liquid obtained by mixing two or more source materials having different boiling points is used as the processing liquid, the source materials may be vaporized in a state in which a ratio of the source materials is maintained by heating the vaporization container 302 at a higher(est) temperature or more of the boiling points of the source materials. Here, the liquid obtained by mixing source materials having different boiling points is a hydrogen peroxide solution.

The above-mentioned hydrogen peroxide solution may react with a metal. Accordingly, the gas supply port 101a, the vaporization unit 101c and the processing liquid supply unit 101b are implemented by a member including a protective film. For example, the member using aluminum is formed of alumite (Al₂O₃), and the member using stainless steel is formed of a chrome oxide film. In addition, ceramics such as Al₂O₃, AlN, SiC, or the like, or a quartz member, other than the metal, may be used. In addition, a mechanism not to be heated may be formed of a material that does not react with the processing liquid, for example, Teflon (trademark), plastic, or the like.

The exhaust unit is implemented by an exhaust valve 105a. According to necessity, the exhaust unit may be configured to include an exhaust pump 105b.

The controller 200 controls the above-mentioned respective parts to cause the automatic valves 111a to 111c, the heater 103, the liquid flow rate control apparatus 113, the gas supply unit, the exhaust unit, a temperature controller 400, and the vaporizer to perform the substrate processing process (to be described below).

Control Unit

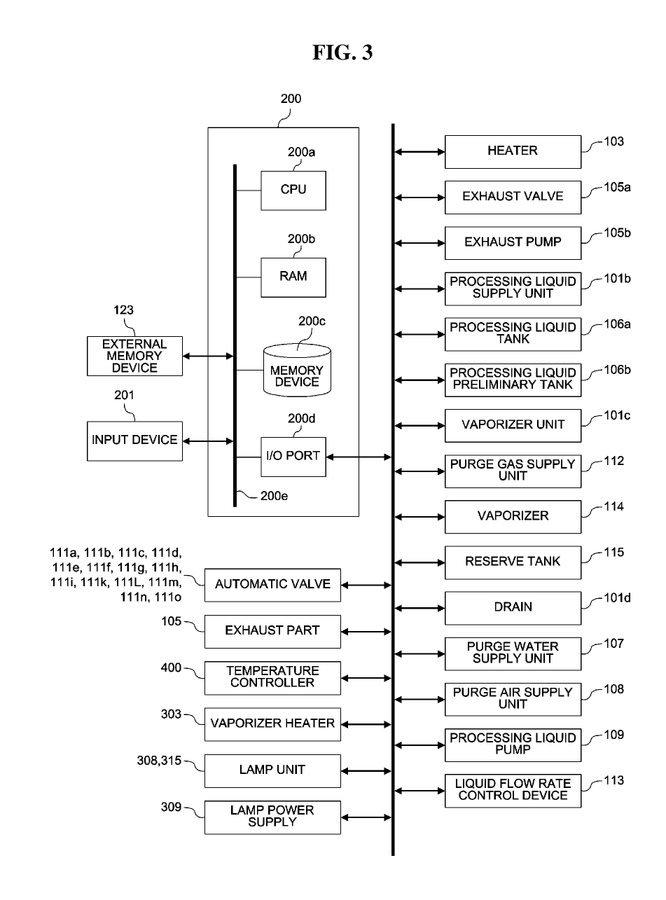

As shown in FIG. 3, the controller 200 serving as a control unit (a control means) is implemented by a computer including a central processing unit (CPU) 200a, a random access memory (RAM) 200b, a memory device 200c, and an input/output (I/O) port 200d. The RAM 200b, the memory device 200c and the I/O port 200d are configured to be capable of data exchange with the CPU 200a through an internal bus 200e. An I/O device 201 implemented by, for example, a touch panel or the like is connected to the controller 200.

The memory device 200c is implemented by, for example, a flash memory, a hard disk drive (HDD), or the like. A control program for controlling an operation of the substrate processing apparatus, a process recipe in which a sequence, a condition, and so on, of the substrate processing (to be described below) are written, and so on, are readably stored in the memory device 200c. In addition, the process recipe, which functions as a program, is combined such that the sequences in the substrate processing process (to be described below) are performed by the controller 200 to obtain a predetermined result. Hereinafter, the process recipe, the control program, and so on, are generally and simply referred to as a program. In addition, when the term “program” is used herein, the program may include only a process recipe, only a control program, or both of them. In addition, the RAM 200b is implemented by a memory region (a work area) in which a program, data, or the like, read by the CPU 200a is temporarily held.

The I/O port 200d is connected to the heater 103, the exhaust valve 105a, the exhaust pump 105b, the processing liquid supply unit 101b, the processing liquid tank 106a, the processing liquid preliminary tank 106b, the vaporization unit 101c, the purge gas supply unit 112, the vaporizer 114, the reserve tank 115, the drain 101d, the purge water supply unit 107, the purge air supply unit 108, the processing liquid pump 109, the automatic valves 111a, 111b and 111c, 111d, 111e, 111f, 111g, 111h, 111i, 111k, 111L, 111m, 111n and 111o, the liquid flow rate control apparatus 113, an exhaust unit 105, the temperature controller 400, the vaporizer heater 303, lamp units 308 and 315 and a lamp power supply 309.

The CPU 200a is configured such that the process recipe from the memory device 200c is read according to an input or the like of an operation command from the I/O device 201 while reading and executing the control program from the memory device 200c. In addition, the CPU 200a is configured to control a flow rate adjustment operation of the processing liquid by the liquid flow rate control apparatus 113, a flow rate adjustment operation of the purge water by the purge water supply unit 107, a flow rate adjustment operation of the purge gas by the purge air supply unit 108, an opening/closing operation of the automatic valves 111a, 111b and 111c, 111d, 111e, 111f, 111g, 111h, 111i, 111k, 111L, 111m, 111n and 111o, an opening angle adjustment operation of the exhaust valve 105a, a temperature control operation by the temperature controller 400, the vaporizer heater 303, the lamp units 308 and 315, and the lamp power supply 309, a liquid supply operation of the processing liquid supply unit 101b, and so on, according to contents of the read process recipe.

In addition, the controller 200 is not limited to be implemented by an exclusive computer but may be implemented by a universal computer. For example, the controller 200 according to the embodiment may be implemented by preparing an external memory device 123 in which the above-mentioned program is stored (for example, a magnetic disk such as a magnetic tape, a flexible disk, a hard disk, or the like, an optical disk such as a CD, a DVD, or the like, a magneto-optical disk such as MO or the like, a USB memory (a USB flash drive), or a semiconductor memory such as a memory card or the like), and installing the program in the universal computer using the external memory device 123. In addition, a means for supplying the program into the computer is not limited to the case in which the program is supplied via the external memory device 123. For example, the program may be supplied through a communication means such as the Internet or an exclusive line, other than the external memory device 123. In addition, the memory device 200c or the external memory device 123 may be implemented by a non-transitory computer readable recording medium. Hereinafter, these may be generally and simply referred to as a recording medium. In addition, when the term “recording medium” is used herein, it may include only the memory device 200c, only the external memory device 123, or both of them.

(2) Substrate Processing Process

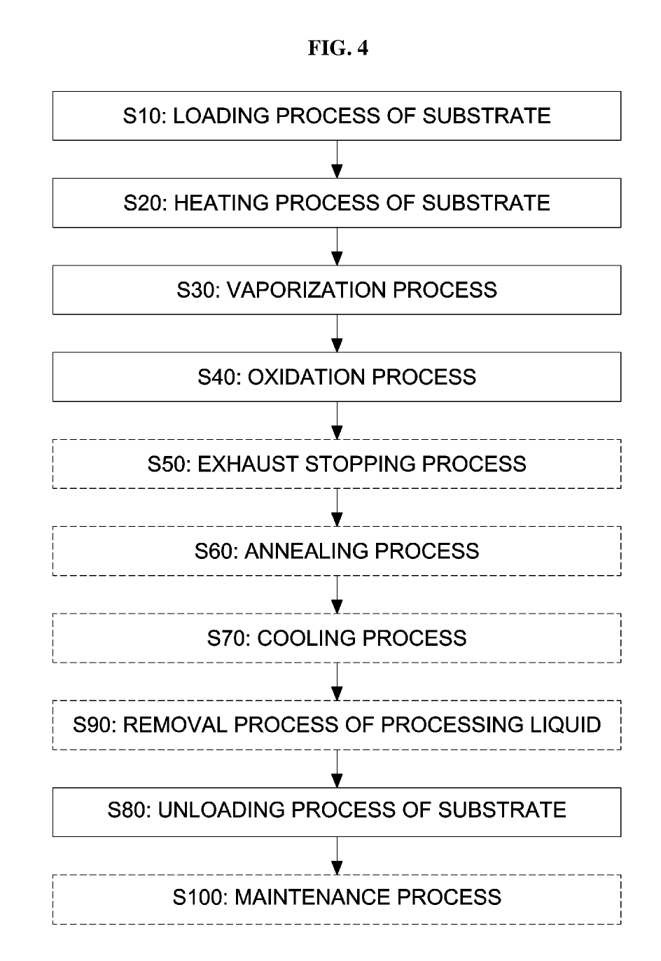

Next, the substrate processing process performed as one process of a semiconductor manufacturing process according to the embodiment will be described using FIG. 4. The process is performed by the above-mentioned substrate processing apparatus. In addition, in the following description, operations of the respective parts constituting the substrate processing apparatus are controlled by the controller 200.

Here, an example in which a silicon oxide film for insulating the respective devices constituting the semiconductor device is formed will be described.

Loading Process (S10) of Substrate

First, the wafer 100, on which the film including a silicon element, a nitrogen element and a hydrogen element is deposited, is stacked on the boat 102, and the boat 102 is loaded into the reaction chamber 104. After the loading, a gas in the reaction chamber 104 is substituted with an inert gas supplied by the exhaust unit and the purge gas supply unit 112, and a concentration of oxygen is reduced. A film including the silicon element, the nitrogen element, and the hydrogen element may be a plasma polymer film or the like of polysilazane or tetrasilylamine and ammonia.

Heating Process (S20) of Substrate

The loaded substrate is heated to a desired temperature by the heater 103 which is previously heated. The desired temperature is, for example, room temperature to 200° C. when hydrogen peroxide is used as the processing liquid. The desired temperature is preferably 40° C. to 100° C., for example, 100° C.

Vaporization Process (S30)

After the wafer 100 is loaded into the reaction chamber 104, the processing liquid is supplied by the processing liquid supply unit 101b into the vaporization unit 101c, and the vaporization process of the hydrogen peroxide solution is performed in the vaporization unit 101c. In the vaporization process, the processing liquid pump 109 sends the hydrogen peroxide solution from the processing liquid tank 106a or the processing liquid preliminary tank 106b into the reserve tank 115. The gas is supplied by the purge gas supply unit 112 into the reserve tank 115 so that the reserve tank 115 is in a state in which a liquid surface of the remaining hydrogen peroxide solution is pressurized. The hydrogen peroxide solution is supplied by the pressure into the liquid flow rate control apparatus 113 from a liquid sending part 116 installed under the liquid surface. The liquid flow rate control apparatus 113 adjusts a flow rate of the hydrogen peroxide solution supplied from the reserve tank 115 to send the hydrogen peroxide solution to the vaporizer 114. As shown in FIG. 2, in the vaporizer 114, the hydrogen peroxide solution is added in drops from the processing liquid dropping nozzle 300 into the heated vaporization container 302. When the dropped hydrogen peroxide solution arrives at the heated vaporization container 302, the dropped hydrogen peroxide solution is heated and vaporized to become a gas. The gasified hydrogen peroxide solution flows from the exhaust port 304 into the reaction chamber 104. The hydrogen peroxide solution includes hydrogen peroxide (H₂O₂) and water (H₂O). While the two materials have different boiling points, in the present method in which the respective materials are immediately heated and vaporized, a source material may be supplied into the reaction chamber 104 without varying amounts of the respective materials in a liquid state and a gas state. In addition, the vaporization process of the hydrogen peroxide solution may be performed before the loading process of the wafer 100.

Oxidation Process (S40)

After heated to the desired temperature, the automatic valve 111L is opened, the vaporized hydrogen peroxide is supplied from the vaporization unit 101c into the reaction chamber 104, and the reaction chamber 104 is filled. The polysilazane deposited on the wafer 100 is hydrolyzed by the hydrogen peroxide supplied into the reaction chamber 104. In addition, Si generated due to the hydrolysis is oxidized by the hydrogen peroxide to form the silicon oxide film. In addition, the pressure in the reaction chamber 104 during the oxidation process may be in a decompressed state or may be in a state pressurized to the atmospheric pressure or more. The pressure may be preferably 50 kPa to 300 kPa (0.5 atm to 3 atm). Since contact probability of the hydrogen peroxide in the vaporized state with the wafer 100 can be increased by the pressurization, processing uniformity or a processing speed can be improved. In order to increase the pressure to the atmospheric pressure or more, an exhaust stopping process (S50) of closing the exhaust valve 105a and stopping the exhaust is performed.

By using hydrogen peroxide, a hydroxy radical (OH*), which is one of active species, may be generated. The polysilazane can be oxidized by the active species. Since the hydroxy radical is a neutral radical in which oxygen and hydrogen are bonded and a simple structure in which hydrogen is bonded to an oxygen molecule, the hydroxy radical may easily permeate into a low density medium.

In addition, it has been found by assiduous research of the inventor that the hydrogen peroxide has a higher permeability than a gaseous state of water (H₂O). Since the thick film polysilazane or the polysilazane formed in a fine space may also be oxidized to the inside thereto using the above property, film characteristics such as permittivity characteristics in a depth direction, density characteristics of the film, or the like, can be uniformized.

Annealing Process (S60)

After oxidation by the hydrogen peroxide, in order to improve quality of the silicon oxide film formed on the wafer 100, annealing is performed according to necessity. After stopping supply of the hydrogen peroxide gas, the reaction chamber 104 is heated to a desired temperature of 400° C. to 1,100° C. and maintained at the temperature while supplying the inert gas by the purge gas supply unit 112 into the reaction chamber 104. Then, an oxygen-containing gas is supplied from an oxygen-containing gas supply source 117 to perform the annealing of the silicon oxide film according to necessity. Here, the oxygen-containing gas is any one of oxygen (O₂), water (H₂O), ozone (O₃), nitrous oxide (NO), and nitrogen dioxide (NO₂), or a mixed gas thereof. In addition, in order to nitrate the formed oxide film, the nitrogen-containing gas may be supplied. The nitrogen-containing gas may be any one of nitrogen (N₂) and ammonia (NH₃), or a mixed gas thereof.

Cooling Process (S70)

The heated wafer 100 is cooled to a conveyable temperature. In addition, the cooling process may be performed after the internal atmosphere of the reaction chamber 104 is substituted with the inert gas such that oxygen is not adsorbed and reacts with the film formed on the wafer 100. In addition, when the annealing process (S60) is not performed, the cooling process (S70) may not be performed.

Unloading Process (S80) of Substrate

After the temperature or gas in the reaction chamber 104 reaches an unloadable state, the unloading is performed. In addition, when the annealing process is not performed, the hydrogen peroxide may remain in the reaction chamber 104. In this case, the unloading process of the substrate is performed after a removal process of the processing liquid is performed.

Removal Process (S90) of Processing Liquid

The remaining hydrogen peroxide or the like may be liquid, and may adhere to the member in the reaction chamber 104. The remaining gas or liquid may form a water spot on the wafer 100 or may corrode the member including a metal present outside the reaction chamber 104. In the removal process, the inside of the reaction chamber 104 is vacuum-exhausted by the exhaust unit 105. The hydrogen peroxide liquefied through the vacuum exhaust is also gasified and discharged. In addition, the discharge of the hydrogen peroxide may be accelerated by supplying the inert gas at an arbitrary timing. For example, the vacuum exhaust and the inert gas are alternately supplied to improve discharge efficiency of the hydrogen peroxide.

Maintenance Process (S100)

In addition, a maintenance process of cleaning or replacing parts is performed in the processing liquid supply unit 101b according to necessity. Since the hydrogen peroxide solution may react with the metal or the like, cleaning of a processing liquid supply pipe is needed before and after the maintenance. First, during the maintenance process, the automatic valves 111a and 111b are closed and supply of the hydrogen peroxide solution is stopped. Next, water including no impurities such as distilled water and the like is supplied from the purge water supply unit 107, and the hydrogen peroxide solution in the processing liquid supply unit 101b and the vaporization unit 101c is removed. The water and hydrogen peroxide supplied into the respective parts remain in the drain 101d. Next, a purge gas is supplied by the purge air supply unit 108 or the purge gas supply unit 112, and water in the processing liquid supply unit 101b and the vaporization unit 101c is removed. The water forced out by the purge remains in the drain 101d. As a result, a process of replacing parts or the like is performed in a state in which the processing liquid in the processing liquid pipe has been removed. As the process is performed, maintenance work may be safely performed.

(3) Effects According to the Embodiment

According to the embodiment, one or a plurality of effects are exhibited as follows:

(a) According to the embodiment, the liquid including two or more materials having different boiling points can be vaporized.

(b) In addition, since the gas including two or more materials having different boiling points can be supplied into the reaction chamber while constantly maintaining an amount when it is liquefied, wafer processing can be performed with good reproducibility.

(c) In addition, since supply of the hydrogen peroxide solution into the vaporizer is continuously performed by installing the reserve tank, a supply amount of the liquefied hydrogen peroxide into the reaction chamber can be constantly maintained, and uniformity of wafer processing or reproducibility of each batch of the wafer processing can be improved.

(d) In addition, as the hydrogen peroxide in a vaporized state is supplied onto the substrate, the polysilazane can be uniformly oxidized in a thickness direction.

(e) In addition, as the hydrogen peroxide solution is used in the processing liquid, the polysilazane film formed on the substrate can be oxidized at a low temperature for a short duration. In addition, reproducibility of each batch of processing of the wafer on which the polysilazane film is formed can be improved.

Hereinabove, while the embodiment of the present invention has been described in detail, the present invention is not limited to the embodiment but may be variously modified without departing from the spirit of the present invention.

In addition, as a result of the assiduous research, it has been found that, as the structure of the vaporizer 114 is improved to increase a supply amount of a gas containing the hydrogen peroxide, a processing speed of the wafer 100, processing uniformity of the wafer 100, or processing reproducibility can be improved. That is, as heating efficiency of the hydrogen peroxide solution is improved, a vaporization amount can be increased. In addition, it has been found that, as the vaporization is performed for a long duration, a temperature of the vaporization container 302 constituting the vaporization space 301 is decreased, vaporization efficiency is decreased. Hereinafter, a vaporizer structure capable of improving vaporization efficiency is described.

### Second Embodiment of the Present Invention

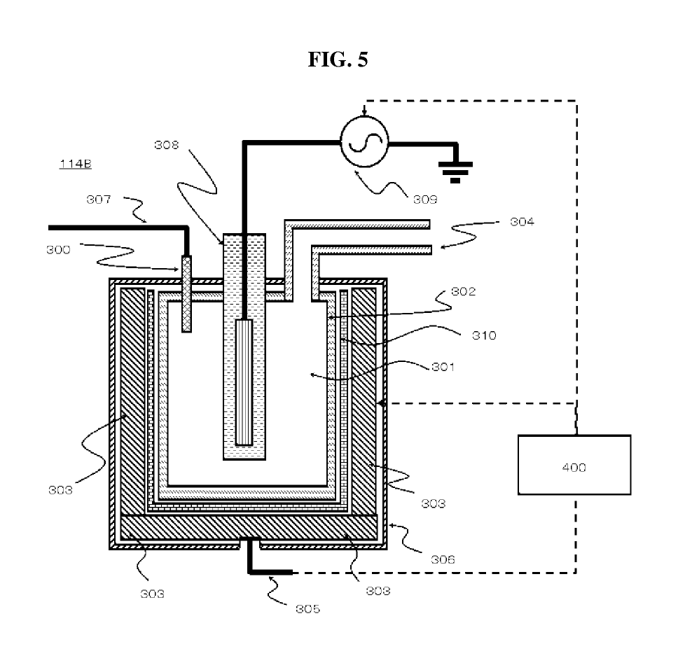

FIG. 5 shows a vaporizer 114B as an example of the vaporizer structure capable of improving vaporization efficiency. The vaporizer 114B is configured to insert the lamp unit 308 serving as a second heating unit into the vaporization space 301 to heat the vaporization space 301 from the inside thereof. While the lamp power supply 309 serving as a power supply of the lamp unit 308 may be always in an ON state, an output thereof may be configured to be controlled by the temperature controller 400. Since the vaporization container 302 may be heated while heating the hydrogen peroxide solution added in drops from the processing liquid dropping nozzle 300 from the inside thereof, the vaporization efficiency of the hydrogen peroxide solution may be improved. In addition, in order to effectively absorb optical energy emitted from the lamp unit 308 into the vaporization container 302 or the hydrogen peroxide solution, a reflective wall 310 may be installed. As the reflective wall 310 is installed, optical energy emitted from the lamp unit 308 may be reflected. The lamp constituting the lamp unit 308 may preferably employ a lamp using carbon as an emitting body. For example, emission from a carbon lamp has a peak wavelength of 2 μm to 2.5 μm, and a material including OH* may be primarily heated. That is, the hydrogen peroxide or the hydrogen peroxide solution may be efficiently heated.

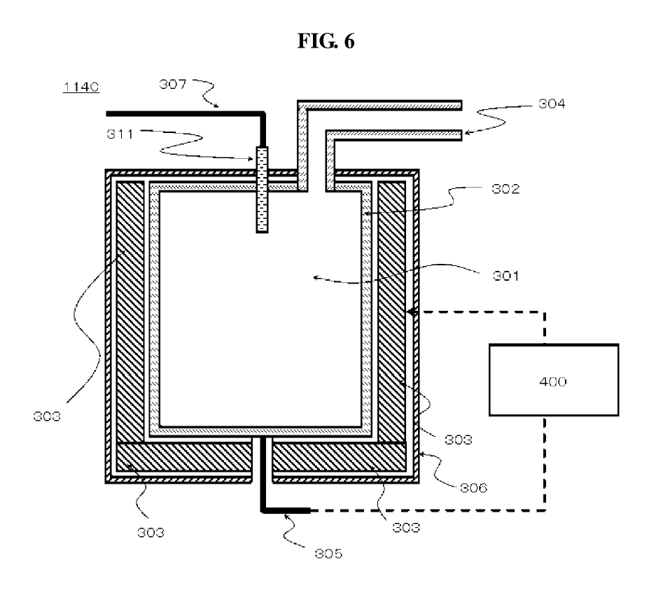

FIG. 6 shows a vaporizer 114C as an example of the vaporizer structure capable of improving the vaporization efficiency. The vaporizer 114C in which a spray nozzle 311 is installed as a processing liquid supply unit is exemplified. As a dropping nozzle is employed as the spray nozzle 311 to reduce a size of the drop of the liquid, heating efficiency of the liquid is improved. Accordingly, the vaporization amount may be increased. In addition, since the processing liquid is not concentrated in one place, condensation of the liquid may be prevented and a surface in the vaporization container 302 may be widely and effectively used.

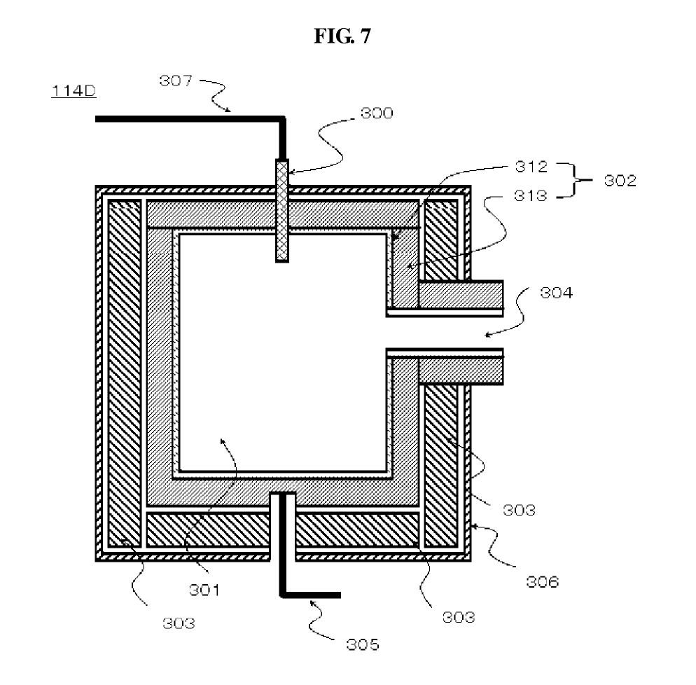

FIG. 7 shows a vaporizer 114D as an example of the vaporizer structure capable of improving the vaporization efficiency. The vaporizer 114D in which the vaporization container 302 is implemented with a thermal conductive member is exemplified. The thermal conductive member includes any one or both of an internal thermal conductive member 312 and an external thermal conductive member 313. For example, the external thermal conductive member 313 that forms the outside is formed of any one of aluminum, stainless steel and carbonized silicon having high thermal conductivity or a mixture thereof, and the internal thermal conductive member 312 installed at the inside is formed of any one of silicon oxide, aluminum oxide, and chrome oxide or a mixture thereof. As the member having high thermal conductivity is used in the external thermal conductive member 313, a local decrease in temperature of the vaporization container 302 can be prevented. In addition, as the oxide is used in the internal thermal conductive member 312, a reaction of the external thermal conductive member 313 with the processing liquid may be prevented. In addition, wettability of the processing liquid may be improved. That is, hydrophobicity of an inner wall of the vaporization container 302 may be reduced, and a contact area with the processing liquid may be increased to improve the vaporization efficiency. The structures of the internal thermal conductive member 312 and the external thermal conductive member 313 are obtained by, for example, forming the external thermal conductive member 313 using aluminum and oxidizing the aluminum of the internal thermal conductive member 312. As described above, when a metal material is used, the external thermal conductive member 313 may be manufactured by oxidizing the metal surface. That is, the external thermal conductive member 313 can be manufactured at a low cost. In addition, as the external thermal conductive member 313 is formed of carbonized silicon, a lifetime of the vaporizer can be increased. That is, when the external thermal conductive member 313 is formed of the metal, while the processing liquid may react with the degraded internal thermal conductive member 312, the carbonized silicon has durability with respect to the effects of the processing liquid, and thus, the lifetime can be increased. In addition, even when the carbonized silicon is used, the oxide film serving as the internal thermal conductive member 312 may be formed by exposing the carbonized silicon to an oxidation atmosphere with a temperature of 700° C. or more, and thus, there is no need of a complex manufacturing process. In addition, as the internal thermal conductive member 312 in contact with the processing liquid is formed of the silicon oxide film, wettability with respect to the processing liquid can be further improved. In addition, the thermal conductive member may be installed at an outer circumference of the vaporization container 302 of FIG. 2.

### Third Embodiment of the Present Invention

In addition, as a result of the assiduous research, it has been found that residual liquid may be generated due to continuous dropping onto the same place in the vaporizer 114. When the residual liquid is generated, it has been found that a continuing low temperature state due to evaporative latent heat causes an unstable vaporization amount. In addition, it has been found that some of the residual liquid of the vaporization container 302 is melted to a very small amount

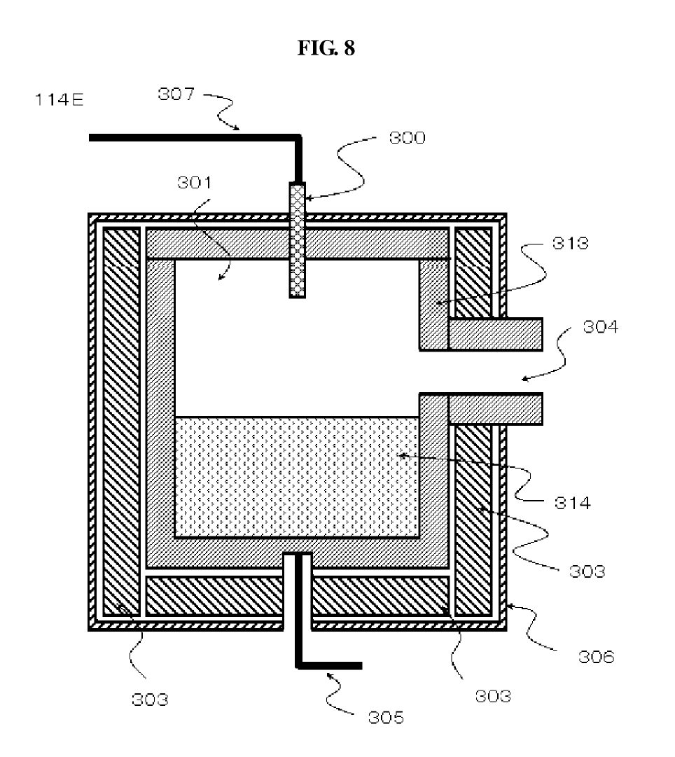

FIG. 8 shows a vaporizer 114E as an example of the vaporizer structure in which the residual liquid is not generated. A vaporizer 114E configured to prevent generation of residual liquid by installing a porous thermal conductive member 314 serving as a residual liquid prevention unit at the vaporization space 301 is exemplified. A porous material is formed with a porosity having a ventilation property to enable an increase in a surface area of a vaporization surface. The hydrogen peroxide solution dropped from a dropping nozzle is not vaporized at the upper most section of the porous thermal conductive member 314 and penetrates into the porous section to move downward. During movement, vaporization and gasification are accelerated to completely vaporize the hydrogen peroxide solution. In the case of the porous structure, since the porous thermal conductive member 314 can be efficiently heated to the uppermost section thereof by solid thermal conduction at an area bonded as a backbone, a decrease in temperature of the evaporative latent heat can be prevented.

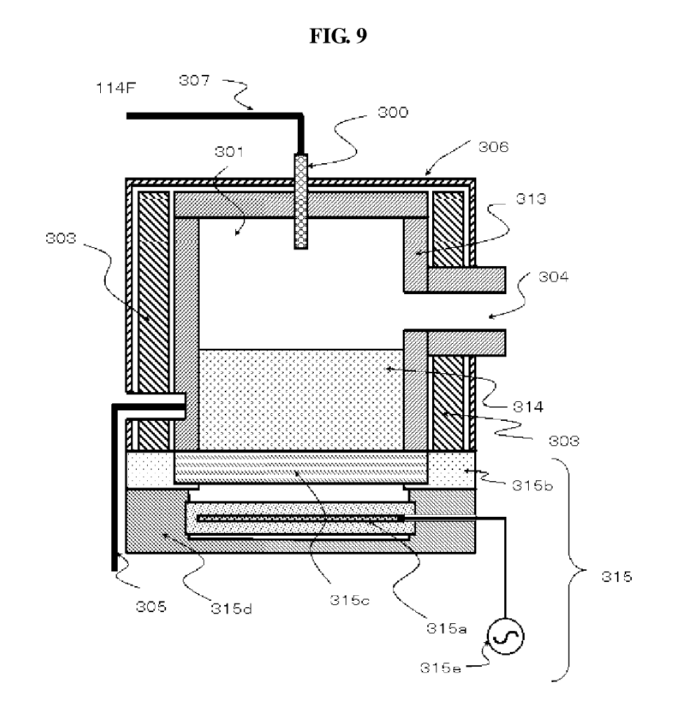

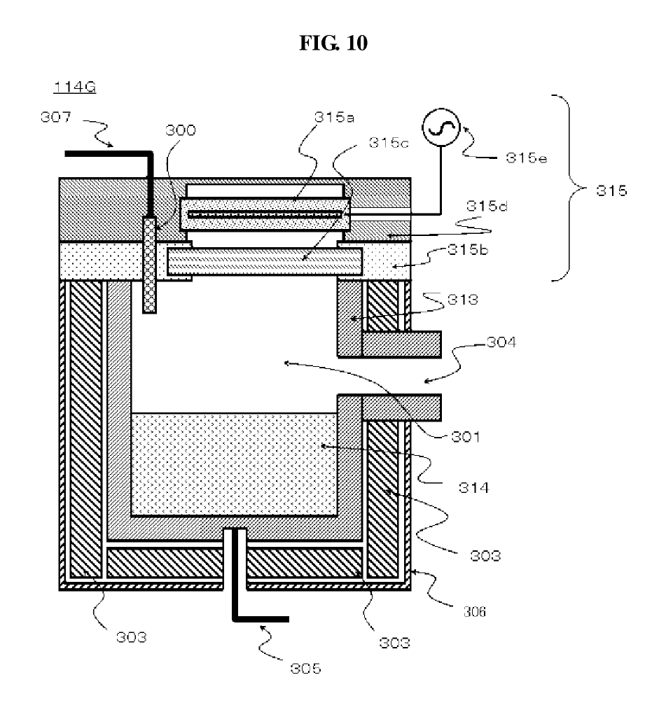

FIG. 9 shows a vaporizer 114F as an example of the vaporizer structure in which the residual liquid is not generated. The vaporizer 114F in which a lamp unit 315 serving as a second heating unit is installed at a lower portion of the porous thermal conductive member 314 is exemplified. Since the inside of the porous structure can be directly heated by the optical energy using the lamp unit 315, heating efficiency of the porous thermal conductive member 314 is improved. As shown in FIG. 9, the lamp unit 315 includes a lamp 315a, a window compression part 315b, a window 315c, a lamp housing 315d and a lamp power supply 315e. The lamp unit 315 may be installed at an upper portion of the porous thermal conductive member 314 as shown in a vaporizer 114G of FIG. 10, or may be installed in the vaporization space 301 as shown in FIG. 5. As the lamp unit is installed at the upper portion of the porous thermal conductive member 314, the uppermost surface of the porous thermal conductive member 314, a temperature of which is likely to be decreased, may be heated. Here, while an example in which the porous thermal conductive member 314 is heated from the lower section or the upper section thereof has been described, the lamp unit 315 may be installed at a side surface or inside of the porous thermal conductive member 314. As the lamp unit 315 is installed inside, the entire porous thermal conductive member 314 may be heated. In addition, the porous thermal conductive member 314 may have a porosity such that the light may pass through from an upper end to a lower end of the porous thermal conductive member 314. As the light passes through, the entire porous thermal conductive member 314 may be heated.

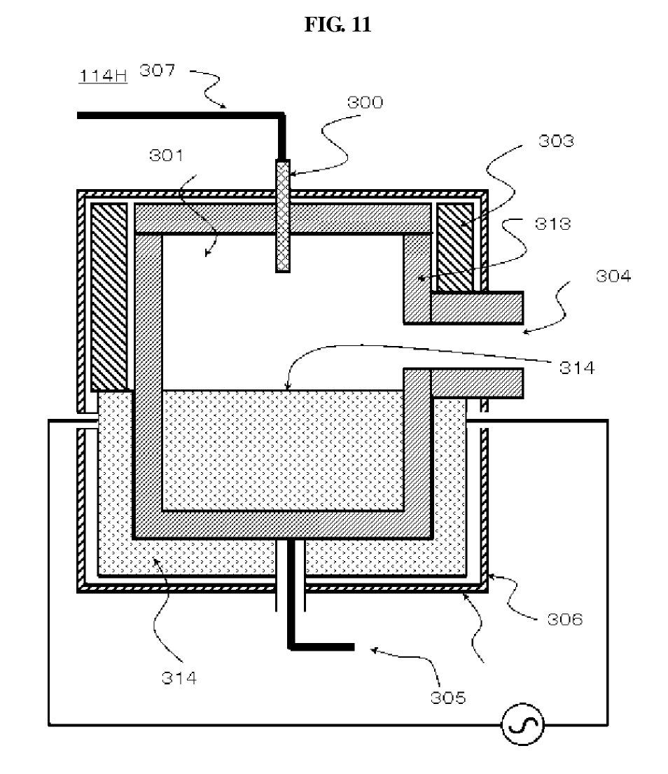

FIG. 11 shows a vaporizer 114H as an example of the vaporizer structure in which the residual liquid is not generated. The vaporizer 114H configured to apply power and heat a portion of the porous thermal conductive member 314 is exemplified. The porous thermal conductive material in the vaporization container 302 is heated via an intermediate thermal conductive material. In addition, when the intermediate thermal conductive material itself has an electrical conductivity, a non-porous material having an external thermal conductivity and electrical conductivity may be disposed therein to be electrically connected to the porous thermal conductive member 314. In this case, the porous thermal conductive member 314 at the inside becomes a heat generating body.

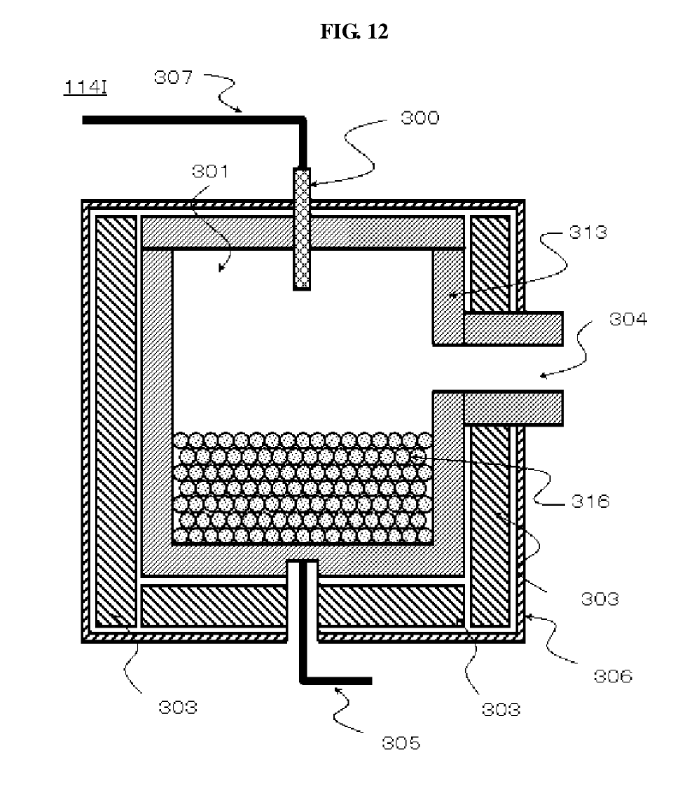

FIG. 12 shows a vaporizer 114I as an example of the vaporizer structure in which the residual liquid is not generated. The vaporizer 114I in which a granular thermal conductive member 316 serving as a residual liquid prevention unit is installed in the vaporization space 301 formed by the external thermal conductive member 313 is exemplified. As the granular thermal conductive member 316 is installed, the processing liquid that is not vaporized at the uppermost section of the granular thermal conductive member 316 moves downward along a surface of a grain. Vaporization and gasification of the non-vaporized processing liquid are accelerated during movement to cause complete vaporization of the processing liquid. The granular thermal conductive member 316 has a spherical shape. As the granular thermal conductive member 316 has the spherical shape, a filling factor of the vaporization space 301 may be increased.

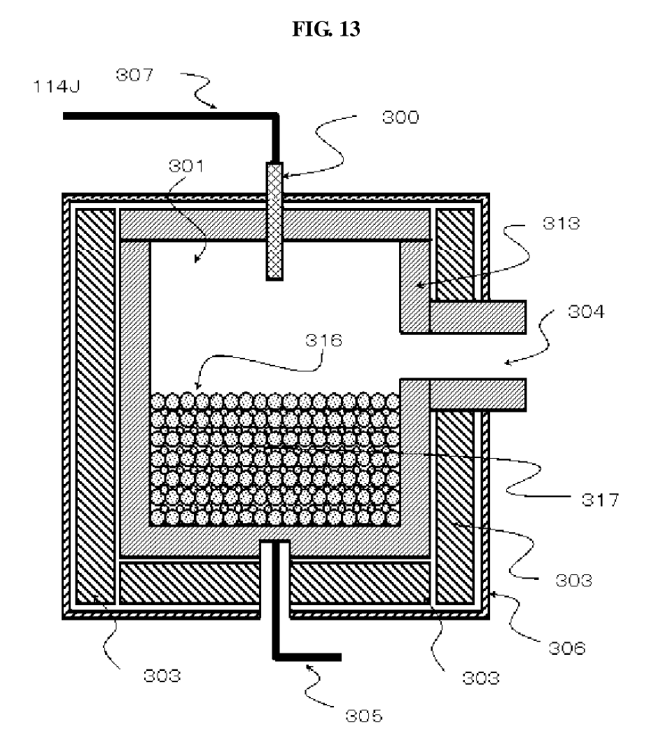

FIG. 13 shows a vaporizer 114J as an example of the vaporizer in which the residual liquid is not generated. The vaporizer 114J in which a fine granular thermal conductive member 317 having a grain diameter smaller than that of the granular thermal conductive member 316 is installed as a second residual liquid prevention unit, except for the granular thermal conductive member 316, is exemplified. When the conductive member is formed of the grains having the same size as shown in FIG. 12, a gap is generated between the grains. Since the gap interrupts the thermal conduction, as the gap is filled with fine grains, vaporization performance can be improved while improving thermal conductivity.

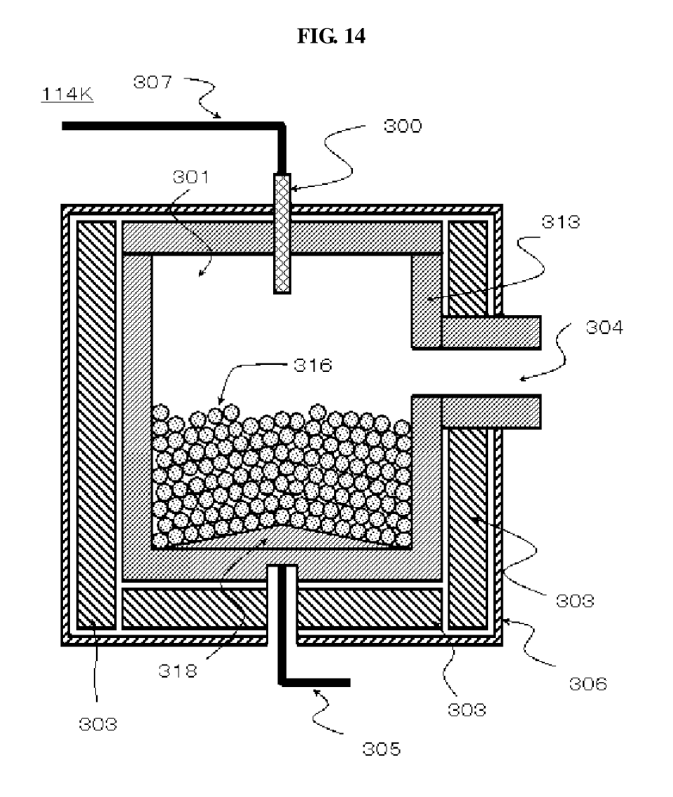

FIG. 14 shows a vaporizer 114K as an example of the vaporizer structure in which the residual liquid is not generated. The vaporizer 114K in which a conical protrusion 318 serving as a protrusion is installed at a lower section of the granular thermal conductive member 316 and a bottom section of the external thermal conductive member 313 is exemplified. As the conical protrusion 318 is installed, the processing liquid may not remain in one place of the external thermal conductive member 313 when the processing liquid arrives at the bottom section of the external thermal conductive member 313. In addition, an inclination is generated in the granular thermal conductive member 316 by the conical protrusion 318, the processing liquid may not be easily transmitted directly downward, and thus, a vaporization surface in contact with the processing liquid may be increased. Here, while a conical shape is shown, the protrusion may have a pyramidal shape, a truncated pyramidal shape, a truncated conical shape, or a shape in which a triangular pillar has fallen down.

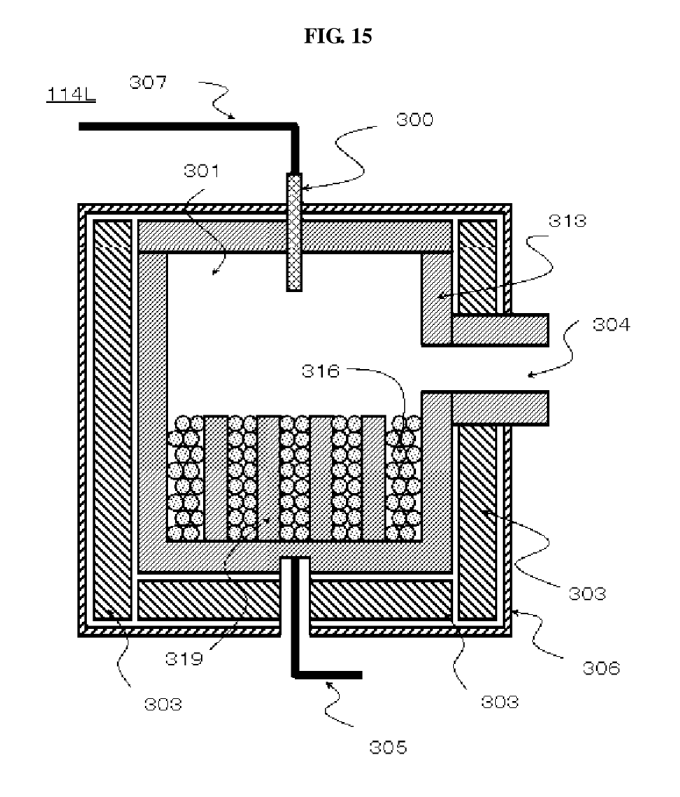

FIG. 15 shows a vaporizer 114L as an example of the vaporizer structure in which the residual liquid is not generated. The vaporizer 114L in which a columnar protrusion 319 serving as a protrusion is installed at a bottom section of the external thermal conductive member 313 is exemplified. The columnar protrusion 319 functions as a heat path to the uppermost section of the granular thermal conductive member 316 to efficiently heat the granular thermal conductive member 316 to the uppermost section thereof. In addition, the columnar protrusion 319 may have a gimlet shape. In addition, the columnar protrusion may have a partition plate shape configured to divide a lower section of the vaporization space 301 into a plurality of zones.

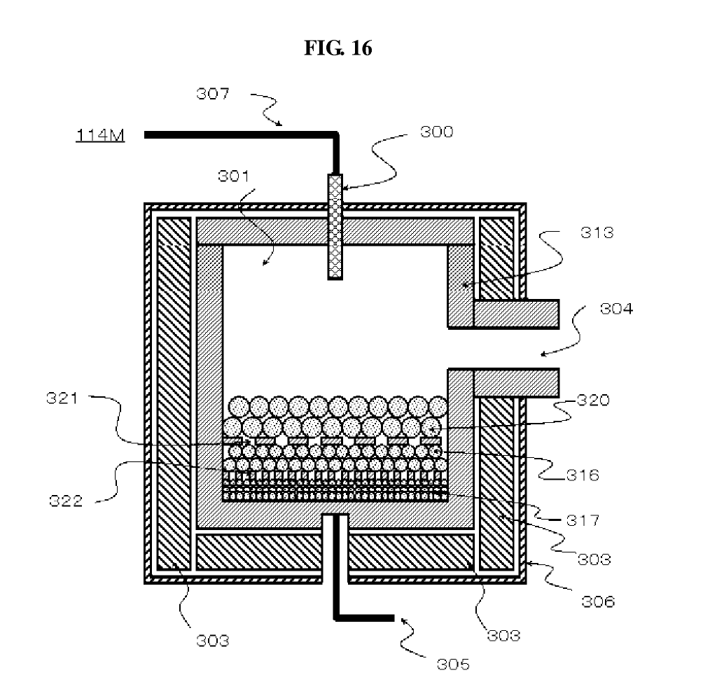

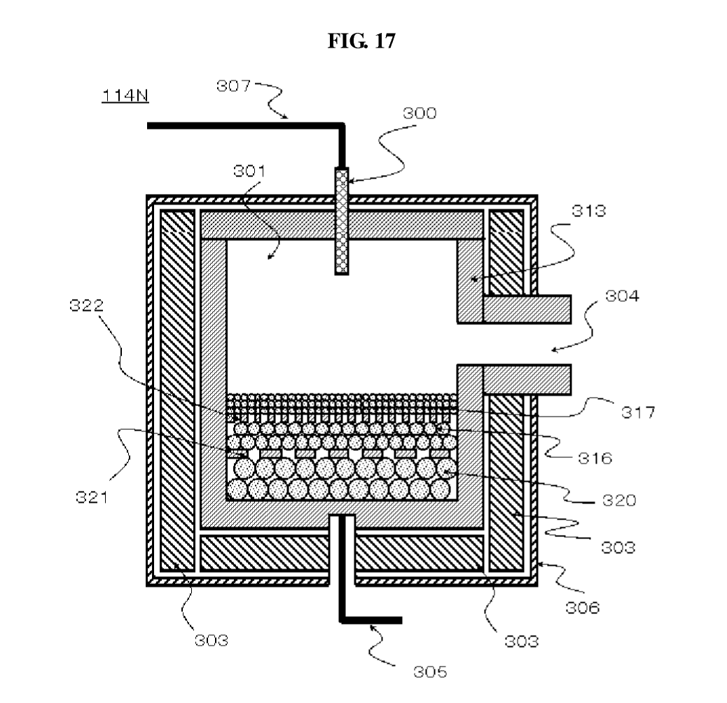

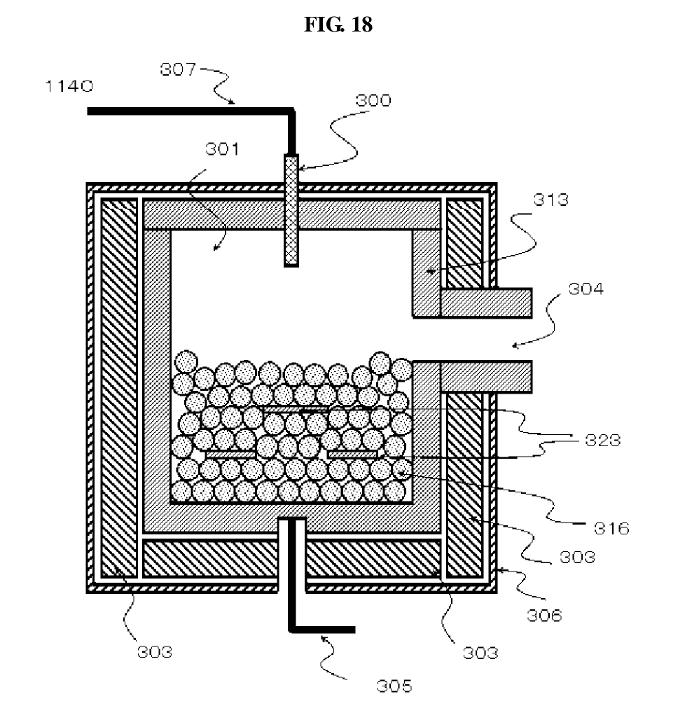

FIG. 16 shows a vaporizer 114M as an example of the vaporizer in which the residual liquid is not generated. The vaporizer 114M in which the granular thermal conductive member 316 serving as a residual liquid prevention unit, the fine granular thermal conductive member 317, the large granular thermal conductive member 320 having a larger particle than that of the granular thermal conductive member 316, and a rough dispersion plate 321 and a fine dispersion plate 322 disposed between the granular thermal conductive member 316, the fine granular thermal conductive member 317 and the large granular thermal conductive member 320 are installed is exemplified. As the dispersion plate is installed, a risk of the liquid remaining in one place may be reduced due to dispersion of the dropped liquid to the surroundings. In addition, the thermal conductive material having a small particle may overlap in sequence from above like the vaporizer 114N shown in FIG. 17, or the particle having the same single size may be used. In addition, a partition plate may be disposed like a vaporizer 114O shown in FIG. 18. As the partition plate is disposed as shown in FIG. 18, the dropped processing liquid may be guided in a horizontal direction. In addition, a hole having an arbitrary shape may be formed in the dispersion plate, or the dispersion plate may have a 3-dimentional structure such as a conical or pyramidal shape, other than a flat plate shape. In addition, only a partition plate 323 may be provided without the granular thermal conductive member 316. For example, as a partition plate having a triangular pillar shape is installed, the dropped processing liquid may be dispersed in the vaporization space 301.

### Another Embodiment of the Present Invention

Hereinabove, while the embodiments of the present invention has been described in detail, the present invention is not limited to the above-mentioned embodiments but may be variously modified without departing from the spirit of the present invention.

For example, in the above-mentioned embodiment, the case in which the wafer 100 on which the polysilazane is deposited is processed has been described, the present invention is not limited thereto but a wafer or a glass substrate having a surface on which a fine concavo-convex structure is formed, a wafer on which the polysilazane is deposited on the fine concavo-convex structure, or a wafer or a glass substrate containing carbon may be similarly processed. As the substrate on which the fine concavo-convex structure is formed is processed, a surface of the concavo-convex structure may be uniformly oxidized. In addition, as the wafer on which the polysilazane is deposited on the fine concavo-convex structure is processed, the polysilazane in the concave section may be uniformly oxidized. Even the case of the glass substrate, since the processing temperature is lower than a softening temperature of the glass, similar processing may be performed.

In addition, for example, in the above-mentioned embodiment, while the case in which the hydrogen peroxide solution is dropped downward from above has been described, the present invention is not limited thereto but the hydrogen peroxide solution may be supplied from a side surface or may be sprayed into the vaporizer from a lower side thereof.

In addition, for example, in the above-mentioned embodiment, while the case in which one dropping nozzle is installed has been described, the present invention is not limited thereto but a plurality of dropping nozzle may be installed to increase a dropping amount. In addition, a nozzle configured to make a small droplet or a large droplet may be provided. As the plurality of nozzles are installed, a vapor amount of the hydrogen peroxide may be increased. In addition, the vapor amount may be increased by reducing the size of the droplet. On the contrary, when the vapor amount is excessively large or a decrease in a temperature of the vaporization container is severe, the vapor amount may be adjusted to an appropriate amount by reducing the number of nozzles.

In addition, for example, a configuration in which elements of the above-mentioned vaporizers 114A to 114O are combined may be provided. The vapor amount of the processing liquid may be increased through the combination.

In addition, in the above-mentioned embodiment, the vaporized gas may include a state of a single source molecule or a cluster state in which a plurality of molecules are bonded. In addition, when the gas is generated from the liquid, the liquid may be bound to the single body of the source molecule or may be bound to the cluster state in which the plurality of molecules are bonded. In addition, when the processing quality is decreased, the liquid may be in a mist state in which the plurality of clusters are gathered.

In addition, hereinabove, while the processing of manufacturing the semiconductor device has been described, the embodiment according to the present invention may be applied to the other processes in addition to the process of manufacturing the semiconductor device. For example, the present invention may be applied to a sealing process of the substrate including liquid crystal in a process of manufacturing a liquid crystal device, or a coating process of a glass substrate, a ceramic substrate or a plastic substrate used in various devices. In addition, the present invention may be applied to a water-repellent coating process of a mirror or the like.

In addition, hereinabove, while the example in which the substrate, on which the polysilazane is deposited, is processed has been described, the present invention is not limited thereto. The material may include silazane bonding (Si-N bonding). For example, a film on which hexamethyldisilazane (HMDS), hexamethylcyclotrisilazane (HMCTS), polycarbosilazane, or polyorganosilazane is deposited may be provided.

In addition, otherwise, for example, a substrate on which a silicon-containing film is formed by a CVD method using a silicon (Si) source material such as monosilane (SiH₄) gas, trisilylamine (TSA) gas, or the like, may be employed.

According to the substrate processing apparatus, the method of manufacturing the semiconductor device, and the vaporizer of the present invention, the oxide film can be formed at a low temperature for a short duration.

### Exemplary Modes of the Present Invention

Hereinafter, exemplary modes of the present invention are supplementarily noted.

Supplementary Note 1

According to an aspect of the present invention, there is provided a substrate processing apparatus including: a reaction chamber configured to process a substrate; a vaporizer including a vaporization container into which a processing liquid is supplied, a processing liquid supply unit configured to supply the processing liquid to the vaporization container, and a heating unit configured to heat the vaporization container; a gas supply unit configured to supply a processing gas generated by the vaporizer into the reaction chamber; an exhaust unit configured to exhaust an atmosphere in the reaction chamber; and a control unit configured to control the heating unit and the processing liquid supply unit such that the processing liquid supply unit supplies the processing liquid to the vaporization container while the heating unit heats the vaporization container.

Supplementary Note 2

In the substrate processing apparatus of Supplementary note 1, preferably, the processing liquid supply unit may be a processing liquid dropping nozzle.

Supplementary Note 3

In the substrate processing apparatus of Supplementary note 1, the processing liquid may contain an oxygen element.

Supplementary Note 4

In the substrate processing apparatus of Supplementary note 1, preferably, the processing liquid may formed by mixing at least two liquids having different boiling points.

Supplementary Note 5

In the substrate processing apparatus of Supplementary note 1, preferably, the processing liquid may be any one of hydrogen peroxide and a mixed liquid of hydrogen peroxide and water.

Supplementary Note 6

In the substrate processing apparatus of Supplementary note 1, preferably, a reserve tank may be installed at a front stage of the vaporizer.

Supplementary Note 7

In the substrate processing apparatus of Supplementary note 1, preferably, a temperature controller configured to control the heating unit installed at the vaporizer may be installed at the vaporizer.

Supplementary Note 8

In the substrate processing apparatus of Supplementary note 1, preferably, a film containing a silicon element, a nitrogen element and a hydrogen element may be formed on the substrate.

Supplementary Note 9

In the substrate processing apparatus of Supplementary note 1, preferably, a film containing silazane bonding may be formed on the substrate.

Supplementary Note 10

In the substrate processing apparatus of Supplementary note 9, preferably, the film including the silazane bonding may be a film including polysilazane.

Supplementary Note 11

In the substrate processing apparatus of Supplementary note 1, preferably, a second heating unit may be installed at the vaporizer.

Supplementary Note 12

In the substrate processing apparatus of Supplementary note 1, preferably, the processing liquid supply unit of the vaporizer may be a spray nozzle.

Supplementary Note 13

In the substrate processing apparatus of Supplementary note 1, preferably, a thermal conductive member may be installed at the vaporizer.

Supplementary Note 14

In the substrate processing apparatus of Supplementary note 13, preferably, the thermal conductive member is formed of any one of an internal thermal conductive member and external thermal conductive member, or both of them.

Supplementary Note 15

In the substrate processing apparatus of Supplementary note 14, preferably, the internal thermal conductive member may be formed of an oxide- or carbon-containing material, and the external thermal conductive member is formed of any one of a metal, a ceramic and quartz, and a mixture thereof.

Supplementary Note 16

In the substrate processing apparatus of Supplementary note 15, preferably, the oxide may be silicon oxide, the carbon-containing material may be silicon carbide, the metal may be aluminum or stainless steel, and the ceramic may be aluminum oxide, carbonized silicon, or aluminum nitride.

Supplementary Note 17

In the substrate processing apparatus of Supplementary note 1, preferably, a residual liquid prevention unit may be installed at the vaporizer.

Supplementary Note 18

In the substrate processing apparatus of Supplementary note 17, preferably, a power supply part may be installed at the residual liquid prevention unit.

Supplementary Note 19

In the substrate processing apparatus of Supplementary note 17, preferably, a second residual liquid prevention unit may be installed at the vaporizer.

Supplementary Note 20

In the substrate processing apparatus of Supplementary note 1, preferably, a protrusion may be installed at a bottom section of a vaporization container of the vaporizer.

Supplementary Note 21

In the substrate processing apparatus of Supplementary note 1, preferably, a dispersion plate may be installed at the vaporizer.

Supplementary Note 22

In the substrate processing apparatus of Supplementary note 1, preferably, a partition plate may be installed at the vaporizer.

Supplementary Note 23

In the substrate processing apparatus of Supplementary note 1, preferably, a reaction chamber heating unit may be installed at the reaction chamber.

Supplementary Note 24

In the substrate processing apparatus of Supplementary note 1, preferably, the heating unit may include a control unit configured to control the heating unit and the processing liquid supply unit such that the processing liquid is supplied into the vaporization container while heating the vaporization container.

Supplementary Note 25

In the substrate processing apparatus of Supplementary note 1, preferably, the heating unit may include a control unit configured to control the heating unit, the processing liquid supply unit and the exhaust unit such that exhaust of the reaction chamber is stopped when the processing liquid is supplied into the vaporization container while heating the vaporization container.

Supplementary Note 26

According to another aspect of the present invention, there is provided a method of processing a substrate including: loading a substrate into a reaction chamber; heating a vaporization container installed at a vaporizer; supplying a processing liquid to the vaporization container; and causing the vaporizer to supply a processing gas generated by the vaporizer into the reaction chamber.

Supplementary Note 27

According to another aspect of the present invention, there is provided a method of manufacturing a semiconductor device including loading a substrate into a reaction chamber; heating a vaporization container installed at a vaporizer; supplying a processing liquid to the vaporization container; and causing the vaporizer to supply a processing gas generated by the vaporizer into the reaction chamber.

Supplementary Note 28

In the method of manufacturing the semiconductor device of Supplementary note 27, preferably, the processing liquid may be formed by mixing at least two liquids having different boiling points.

Supplementary Note 29

In the method of manufacturing the semiconductor device of Supplementary note 27, preferably, the processing liquid may contain an oxygen element.

Supplementary Note 30

In the method of manufacturing the semiconductor device of Supplementary note 27, preferably, the processing liquid may be any one of hydrogen peroxide and a mixed liquid of hydrogen peroxide and water.

Supplementary Note 31

In the method of manufacturing the semiconductor device of Supplementary note 27, preferably, a film containing a silicon element, a nitrogen element and a hydrogen element may be formed on the substrate.

Supplementary Note 32

In the method of manufacturing the semiconductor device of Supplementary note 27, preferably, a film including a silazane bonding may be formed on the substrate.

Supplementary Note 33

In the method of manufacturing the semiconductor device of Supplementary note 32, preferably, the film including the silazane bonding may be a polysilazane film.

Supplementary Note 34

In the method of manufacturing the semiconductor device of Supplementary note 27, preferably, the processing liquid may be at least two liquids having different boiling points, and the method may include a process of controlling a temperature of the vaporization container to a temperature equal to or greater than the higher(est) of the boiling points of the liquids.

Supplementary Note 35

In the method of manufacturing the semiconductor device of Supplementary note 27, preferably, the process of supplying the processing gas into the reaction chamber may include a process of stopping the exhaust process.

Supplementary Note 36

According to still another aspect of the present invention, there is provided a vaporizer including: a processing liquid supply unit configured to supply a processing liquid including hydrogen peroxide or a mixed liquid of hydrogen peroxide and water into a vaporization container; a heating unit configured to heat the vaporization container; and an exhaust port configured to discharge a processing gas generated from the processing liquid.

Supplementary Note 37

In the vaporizer of Supplementary note 36, preferably, the vaporization container configured to heat the processing liquid supply unit and the heating unit may contain a silicon element.

Supplementary Note 38

In the vaporizer of Supplementary note 36, preferably, the vaporizer may include a temperature controller configured to control the heating unit and the processing liquid supply unit to a temperature equal to or higher than a boiling point of the processing liquid when the processing liquid supply unit supplies the processing liquid to the vaporization container.

Supplementary Note 39

In the vaporizer of Supplementary note 36, preferably, a second heating unit may be installed at the vaporizer.

Supplementary Note 40

In the vaporizer of Supplementary note 36, preferably, the processing liquid supply unit may be a spray nozzle.

Supplementary Note 41

In the vaporizer of Supplementary note 36, preferably, a thermal conductive member may be installed.

Supplementary Note 42

In the vaporizer of Supplementary note 41, preferably, the thermal conductive member may be formed at least one of an internal thermal conductive member and an external thermal conductive member.

Supplementary Note 43

In the vaporizer of Supplementary note 42, preferably, the internal thermal conductive member may be formed of oxide or a carbon-containing material, and the external thermal conductive member may be formed of any one of a metal, a ceramic and quartz, or a mixture thereof.

Supplementary Note 44

In the vaporizer of Supplementary note 43, preferably, the oxide may be silicon oxide, the carbon-containing material may be silicon carbide, the metal may be aluminum or stainless, and the ceramics may be aluminum oxide, carbonized silicon, or aluminum nitride.

Supplementary Note 45

In the vaporizer of Supplementary note 36, preferably, a residual liquid prevention unit may be installed at the vaporizer.

Supplementary Note 46

In the vaporizer of Supplementary note 45, preferably, a second residual liquid prevention unit may be installed at the vaporizer.

Supplementary Note 47

In the vaporizer of Supplementary note 45, preferably, the residual liquid prevention unit may be a protrusion, and installed at a bottom section of the vaporization container.

Supplementary Note 48

In the vaporizer of Supplementary note 36, preferably, a dispersion plate may be installed.

Supplementary Note 49

According to another aspect of the present invention, there is provided a method of manufacturing a semiconductor device including: loading a substrate into a reaction chamber; supplying a processing liquid into a vaporizer; causing a processing liquid supply unit installed at the vaporizer to supply the processing liquid into a vaporization container heated by a heating unit installed at the vaporizer; causing an exhaust unit to exhaust an atmosphere in the reaction chamber; unloading the substrate from the reaction chamber; and performing maintenance of the vaporizer including supplying purge water into the vaporizer and supplying a purge gas.

Supplementary Note 50

According to still another aspect of the present invention, there is provided a program configured to execute, in a computer, a sequence of supplying a processing liquid into a vaporizer; a sequence of causing a processing liquid supply unit installed at the vaporizer to supply the processing liquid into a vaporization container heated by a heating unit installed at the vaporizer; a sequence causing the vaporizer to supply a processing gas into the reaction chamber; and a sequence of causing an exhaust unit to exhaust an atmosphere in the reaction chamber.

Supplementary Note 51

According to still another aspect of the present invention, there is provided a non-transitory computer readable recording medium on which program executable by a computer is recorded, the program including: a sequence of supplying a processing liquid into a vaporizer; a sequence of causing a processing liquid supply unit installed at the vaporizer to supply the processing liquid into a vaporization container heated by a heating unit installed at the vaporizer; a sequence of causing the vaporizer to supply a processing gas into the reaction chamber; and a sequence of causing an exhaust unit to exhaust an atmosphere in the reaction chamber.

Supplementary Note 52

In the non-transitory computer readable recording medium of Supplementary note 51, preferably, the program may include a sequence of controlling the heating unit such that a temperature of the member is at or above a boiling point of the processing liquid

Supplementary Note 53

In the non-transitory computer readable recording medium of Supplementary note 51, preferably, the program may include a sequence of unloading a substrate from the reaction chamber; and a maintenance sequence of the vaporizer including a sequence of supplying purge water into the vaporizer and a sequence of supplying a purge gas.

Supplementary Note 54

In the non-transitory computer readable recording medium of Supplementary note 51, preferably, the sequence of supplying the processing gas into the reaction chamber may include a sequence of stopping the exhaust process.

According to the substrate processing apparatus, the method of manufacturing the semiconductor device and the vaporizer of the present invention, the oxide film may be formed at a low temperature for a short duration.

What is claimed is:

1. A substrate processing apparatus comprising:
a reaction chamber configured to process a substrate;
a vaporizer including:
a vaporization container supplied with a processing liquid including hydrogen peroxide or hydrogen peroxide and water;
a processing liquid supply unit configured to supply the processing liquid to the vaporization container; and
a heating unit configured to heat the vaporization container;
a gas supply unit configured to supply a processing gas generated by the vaporizer into the reaction chamber;
an exhaust unit configured to exhaust an inner atmosphere of the reaction chamber; and
a control unit configured to control the heating unit and the processing liquid supply unit in a manner that the processing liquid supply unit supplies the processing liquid to the vaporization container while the heating unit heats the vaporization container.

2. The substrate processing apparatus according to claim 1, wherein the processing liquid supply unit comprises a processing liquid dropping nozzle configured to add the processing liquid in drops.

3. The substrate processing apparatus according to claim 1, wherein a film including a silazane bonding is disposed on the substrate.

4. The substrate processing apparatus according to claim 3, wherein the film including the silazane bonding is a polysilazane film.

5. The substrate processing apparatus according to claim 1, wherein the control unit is configured to control the heating unit to a temperature equal to or higher than a boiling point of the processing liquid.

6. The substrate processing apparatus according to claim 1, wherein the control unit is configured to control the exhaust unit to stop exhausting the inner atmosphere of the reaction chamber when the processing gas generated by the vaporizer is supplied into the reaction chamber.

7. A method of manufacturing a semiconductor device, comprising:
(a) loading a substrate into a reaction chamber;
(b) heating a vaporization container of a vaporizer;
(c) supplying a processing liquid including hydrogen peroxide or hydrogen peroxide and water into the vaporization container; and
(d) supplying a processing gas generated by the vaporizer into the reaction chamber.

8. The method according to claim 7, wherein a film including a silazane bonding is formed on the substrate.

9. The method according to claim 8, wherein the film including the silazane bonding is a polysilazane film.

10. The method according to claim 7, wherein (b) comprises heating the vaporization container to a temperature equal to or higher than a boiling point of the processing liquid.

11. The method according to claim 7, wherein (d) comprises stopping exhausting an inner atmosphere of the reaction chamber.

12. A vaporizer comprising:
a processing liquid supply unit configured to supply a processing liquid including hydrogen peroxide or a mixed liquid of hydrogen peroxide and water to a vaporization container;
a heating unit configured to heat the vaporization container; and
an exhaust port configured to discharge a processing gas generated from the processing liquid.

13. The vaporizer according to claim 12, further comprising a temperature controller configured to control the heating unit to heat the vaporization container to a temperature equal to or higher than a boiling point of the processing liquid while the processing liquid supply unit supplies the processing liquid to the vaporization container.

14. The vaporizer according to claim 13, further comprising a thermal conductive member disposed at at least one of the inside and the outside of the vaporization container.

15. The vaporizer according to claim 13, further comprising a residual liquid prevention unit installed in the vaporization container.
